(19) United States
(12) Patent Application Publication
(10) Pub. No.: US 2021/0167746 A1
(43) Pub. Date: Jun. 3, 2021

(54) DISTRIBUTED VARACTOR NETWORK WITH EXPANDED TUNING RANGE

(71) Applicants: Asmita DANI, Palo Alto, CA (US); Metawave Corporation, Carlsbad, CA (US)

(72) Inventor: Asmita Dani, Carlsbad, CA (US)

(21) Appl. No.: 17/047,965

(22) PCT Filed: Apr. 19, 2019
(86) PCT No.: PCT/US2019/028310

§ 371 Date: Oct. 15, 2020

Related U.S. Application Data
(60) Provisional application No. 62/660,216, filed on Apr. 19, 2018.

(51) Int. Cl. H03H 7/18; H01Q 3/36; H04B 7/06

(52) U.S. Cl. CPC H03H 7/18; H04B 7/0617; H01Q 3/36

(57) ABSTRACT

Examples disclosed herein relate to a phase shift network system including a phase shift network having a plurality of distributed varactor networks, each distributed varactor network capable of providing a phase shift range in a millimeter wave spectrum, and a plurality of switches coupled to the phase shift network, each switch to activate a distributed varactor network from the plurality of distributed varactor networks to generate a given phase shift within the phase shift range.

### CROSS-REFERENCE TO RELATED APPLICATIONS

This application claims priority to U.S. Provisional Application No. 62/660,216, filed on Apr. 19, 2018, and incorporated herein by reference in its entirety.

### BACKGROUND

A varactor is a variable capacitance diode whose capacitance varies with an applied reverse bias voltage. By changing the value of the applied voltage, the capacitance of the varactor is changed over a given range of values. Varactors are used in many different circuits and applications, including, for example, advanced millimeter wave applications in wireless communications and Advanced Driver Assistance Systems (“ADAS”) that demand higher bandwidth and data rates. The millimeter wave spectrum covers frequencies between 30 and 300 GHz and is able to reach data rates of 10 Gbits/s or more with wavelengths in the 1 to 10 mm range. The shorter wavelengths have distinct advantages, including better resolution, high frequency reuse and directed beamforming that are critical in wireless communications and autonomous driving applications. The shorter wavelengths are, however, susceptible to high atmospheric attenuation and have a limited range (just over a kilometer).

Millimeter wave applications, although attracting heightened interest, present significant challenges for device and circuit designers. In particular, the design of varactors for millimeter wave applications suffer from quality factor and tuning range limitations, with the quality factor falling well below desired levels. Varactors having a broad tuning range in millimeter wave are therefore hard to achieve, thereby limiting their use in millimeter wave applications that may require a 360° phase shift to realize their full potential.

### BRIEF DESCRIPTION OF THE DRAWINGS

The present application may be more fully appreciated in connection with the following detailed description taken in conjunction with the accompanying drawings, which are not drawn to scale and in which like reference characters refer to like parts throughout, and wherein:

FIG. 1 illustrates a schematic diagram of a circuit for increasing the tuning range and phase coverage of an ideal varactor in accordance with various examples;

FIG. 2 shows the Smith charts at each reference plane illustrated in the distributed varactor network of FIG. 1;

FIG. 3 is a schematic diagram of a distributed varactor network for millimeter wave applications in accordance with various examples;

FIG. 4 shows the Smith charts at each reference plane illustrated in the distributed varactor network of FIG. 3;

FIG. 5 shows a phase shift network incorporating the distributed varactor network of FIG. 3 to achieve up to a full 360° phase shift;

FIG. 6 is a schematic diagram of an example millimeter wave antenna system utilizing the phase shift network of FIG. 5; and

FIG. 7 shows a schematic diagram of an array of MTS cells for use in the antenna system of FIG. 6.

### DETAILED DESCRIPTION

A distributed varactor network with an expanded tuning range and phase shift coverage is disclosed. The distributed varactor network is implemented with multiple varactors and other components and is suitable for many different applications, including those in the millimeter wave spectrum. In various examples, the distributed varactor network can be incorporated in a phase shift network design to achieve a full 360° phase shift. The phase shift network integrates multiple distributed varactor networks with Radio Frequency (“RF”) switches to provide any desired phase shift up to a full 360° at considerably lower loss than conventional phase shift networks.

In various examples, the phase shift network is implemented in advanced millimeter wave applications in wireless communications, ADAS, and autonomous driving, and in particular, in those applications making use of radiating structures to generate wireless and radar signals having improved directivity and reduced undesired radiation patterns, e.g., side lobes. Such radiating structures may include novel meta-structures (“MTS”) with unprecedented capabilities in manipulating electromagnetic waves as desired. An MTS structure is an engineered structure with electromagnetic properties not found in nature, where the index of refraction may take any value. An MTS structure may be aperiodic, periodic, or partially periodic (semi-periodic.) MTS structures manipulate electromagnetic waves' phase as a function of frequency and spatial distribution and may have a variety of shapes and configurations. MTS structures may be designed to meet certain specified criteria, including, for example, desired beam characteristics.

In various examples, the phase shift network is integrated into an MTS-based antenna system that provides smart beam steering and beam forming using MTS radiating structures in a variety of configurations. The phase shift network described herein enables fast scans of up to 360° of an entire environment in a fraction of time of current systems, and supports autonomous driving with improved performance, all-weather/all-condition detection, advanced decision-making and interaction with multiple vehicle sensors through sensor fusion.

Autonomous driving applications are enhanced with the phase shift network described herein incorporated in an MTS-based antenna system, enabling long-range and short-range visibility. In an automotive application, short-range is considered to be within 30 meters of a vehicle, such as to detect a person in a cross walk directly in front of the vehicle, while long-range is considered to be 250 meters or more, such as to detect approaching vehicles on a highway. The MTS-based antenna system incorporating the phase shift network enables automotive radars capable of reconstructing the world around them and are effectively a radar “digital eye,” having true 3D vision and human-like interpretation of the surrounding environment. The ability to capture environmental information early aids control of a vehicle, allowing anticipation of hazards and changing conditions.

In various examples, an MTS-based antenna system steers a highly-directive RF beam that can accurately determine the location and speed of road objects regardless of weather conditions or clutter in an environment. The MTS-based antenna system can be used in a radar system to provide information for 2D image capability as it measures range and azimuth angle, and to provide distance to an object and azimuth angle identifying a projected location on a horizontal plane.

The examples described herein provide enhanced phase shifting of a transmitted RF signal to achieve transmission in the autonomous vehicle range, which in the US is approximately 77 GHz and has a 5 GHz range, specifically, 76 GHz to 81 GHz. The examples described herein also reduce the computational complexity of a radar system and increase its transmission speed. The examples provided accomplish these goals by taking advantage of the properties of MTS structures coupled with novel feed structures.

It is appreciated that, in the following description, numerous specific details are set forth to provide a thorough understanding of the examples. However, it is appreciated that the examples may be practiced without limitation to these specific details. In other instances, well-known methods and structures may not be described in detail to avoid unnecessarily obscuring the description of the examples. Also, the examples may be used in combination with each other.

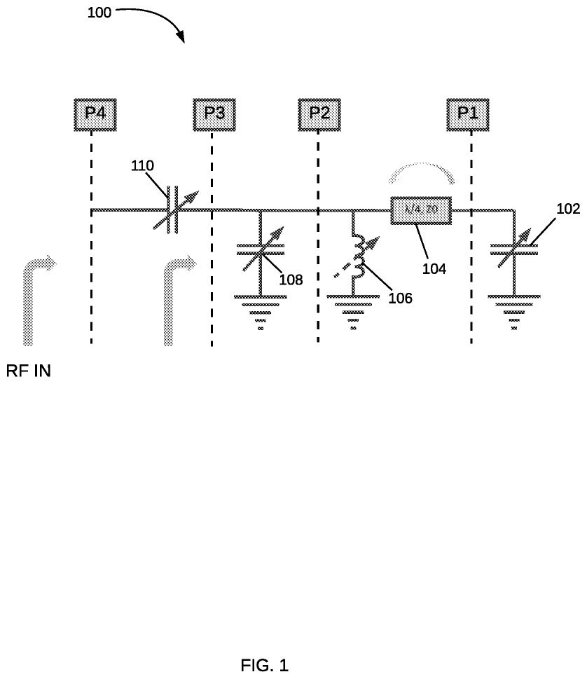

Referring now to FIG. 1, a schematic diagram of a circuit for increasing the tuning range and phase coverage of an ideal varactor in accordance with various examples is described. Consider an ideal varactor 102, i.e., a lossless non-linear reactance, with a given capacitance range (e.g., 20 to 80 fF) and no loss (Rs=0Ω). The ideal varactor 102 can provide a phase shift in the range of about 52 to 126 degrees. Note that as an ideal varactor, this phase shift can occur in different spectrums, including a millimeter wave spectrum in the 30 to 300 GHz. In various applications where a full 360° phase shift is desired, this phase shift of the ideal case is not sufficient.

Circuit 100 provides a solution to this problem by introducing a distributed varactor network. Distributed varactor network 100 starts by adding a uniform (Z0) transmission line 104 of a quarter of a wavelength, denoted by λ/4, connecting ideal varactor 102 to inductor 106 in parallel with varactor 102. This creates a variable LC parallel circuit that can result in a purely inductive or purely capacitance reactance based on the value of varactor 102. At reference plane P2, the variable capacitance of ideal varactor 102 is transformed to a variable inductance with inductor 106.

The distributed varactor network 100 continues with the addition of another ideal varactor, varactor 108, that is identical to ideal varactor 102. This results in a parallel LC tank circuit, such that at reference plane P3, the tank circuit can behave either purely inductive, purely capacitive or have a resonance that depends on the value of the inductance L of inductor 106 and the capacitance C of varactors 102 and 108.

With the addition of another varactor to the distributed varactor network 100, varactor 110, in series with the parallel tank LC circuit formed by varactors 102 and 108 and inductor 104, at reference plane P4, the distributed varactor network 100 behaves as either purely inductive or purely capacitive. The resulting network 100 forms a series LC or series CC circuit that results in a full 360° phase coverage in a Smith chart as well as a large variable reactance range.

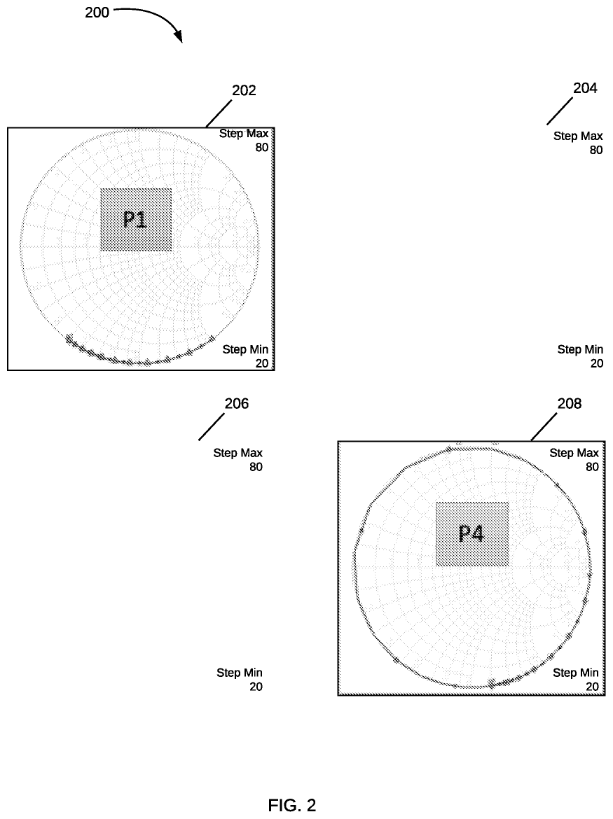

FIG. 2 shows the Smith charts at each reference plane illustrated in the distributed varactor network of FIG. 1. Smith charts 200 include a Smith chart 202 corresponding to reference plane P1 of FIG. 1, a Smith chart 204 corresponding to reference plane P2 of FIG. 1, a Smith chart 206 corresponding to reference plane P3 of FIG. 1, and a Smith chart 208 corresponding to reference plane P4 of FIG. 1. Note that the phase coverage range shown in Smith chart P1 corresponds to the phase coverage range of the varactor 102, an ideal varactor with approximate phase coverage in the 52 to 126 degrees range. At P2, the inductor 106 introduces a phase shift as shown in Smith chart 204. The addition of the ideal varactor 108 in parallel with LC circuit 102-106 results in an expanded phase coverage shown in Smith chart 206. With the varactor 110 placed in series with the LC tank circuit, the phase coverage of the distributed varactor network 100 corresponds to a full 360° as shown in Smith chart 208. As described above, this is highly desirable for many new millimeter wave applications, including autonomous driving applications where a full 360° phase shift enables object detection in a full field of view from the vehicle.

Note, however, that the distributed varactor network 100 achieves the full 360° phase shift in the ideal varactor case. Actual varactors designed for millimeter wave applications suffer from quality factor and tuning range limitations. The tuning range of a millimeter wave varactor is in reality much smaller than that of ideal varactors 102, 108 and 110. In the case of millimeter wave varactors, a different design for a distributed varactor network is needed to achieve broader phase shifts.

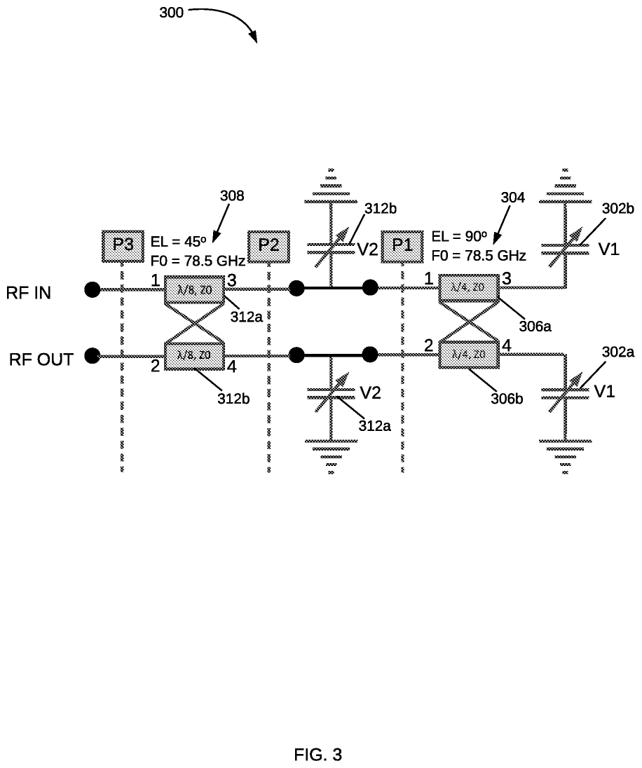

Attention is now directed to FIG. 3, which shows a schematic diagram of a distributed varactor network for millimeter wave applications. Distributed varactor network 300 is designed with varactors that have limited tuning range and quality factors at millimeter waves. In various examples, the varactors are GaAs varactors. In other examples, the varactors can be silicon varactors or other such material. The goal of the distributed varactor network 300 is to expand the tuning range and phase coverage that can be achieved by varactors in millimeter wave applications.

Distributed varactor network 300 achieves this by having distributed phase shifting elements interspersed with varactors and quarter wave transmission line sections. The network 300 starts with varactors 302a-b, which have, for example, low quality factors Q of around 5-6 and a capacitance range of around 37-72 fF in millimeter wave applications. This low Q is a limiting factor in achieving broader phase shifts in millimeter wave applications.

To address this challenge, a 3 dB, 90° hybrid line coupler 304 having wave sections 306a-b of λ/4 is coupled to varactors 302a-b. The hybrid line coupler 304 is a four-port device (labelled as ports 1-4 in FIG. 3) that can split a signal equally into two output ports having a 90° phase shift between them, or that can combine two signals while maintaining high isolation between the ports. The hybrid line coupler 304 together with varactors 302a-b results in a parallel LC circuit.

Adding another hybrid line coupler coupled to two more varactors, this time a 3 dB, 45° hybrid line coupler 308 with wave sections 310a-b of λ/8 coupled to varactors 312a-b with a capacitance range of around 18-33 fF, results in a further increase of phase coverage as it provides another additional series LC-network with the parallel LC circuit formed by coupler 304 and varactors 302a-b.

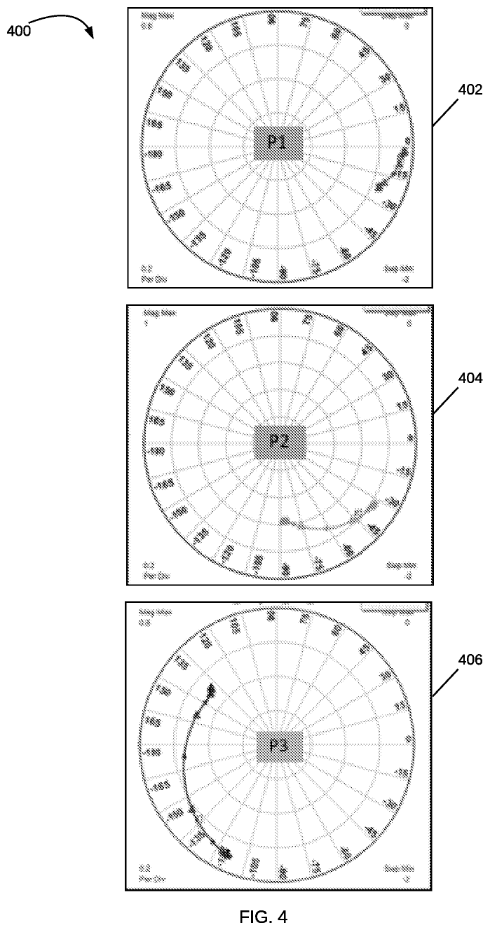

The behavior of distributed varactor network 300 can be further understood with reference to FIG. 4, which shows the Smith charts at each reference plane illustrated in FIG. 3. Smith charts 400 include a Smith chart 402 corresponding to reference plane P1 of FIG. 3, a Smith chart 404 corresponding to reference plane P2 of FIG. 3, and a Smith chart 406 corresponding to reference plane P3 of FIG. 3. Smith chart 402 shows the limited phase range of varactors 302a-b with hybrid coupler 304. The phase range achieved from the hybrid coupler 304 is only about 20°. Adding varactors 312a-b increases the phase shift range to about 55° at reference plane P2, as shown in Smith chart 404. With hybrid coupler 308, the phase shift range increases at reference plane P3 by another 55°, thereby resulting in an overall phase shift range achieved by distributed varactor network of about 110°, as shown in Smith chart 406.

It is appreciated that distributed varactor network 300 can be cascaded with other distributed varactor networks 300 to expand the phase shift range from about 120° to even higher values. However, doing so will result in further loss, which may not be desirable in millimeter wave applications. Distributed varactor network 300 has a loss of up to 6 dB. Cascading another distributed varactor network to it will add another 6 dB.

It is also appreciated that differences in varactor and hybrid coupler implementations (e.g., use of ¼ wave section instead of the ⅛ wave section in coupler 308), may result in variations in their specifications, which may result in variations in the phase shift range achievable by distributed varactor network 300. For example, simulations have shown that phase shift ranges of 120° or more may be achievable with distributed varactor network 300.

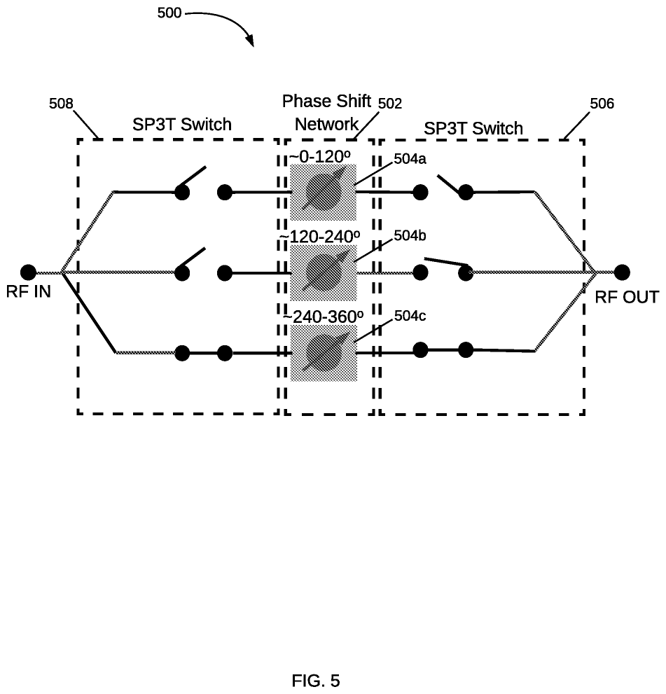

Attention is now directed at FIG. 5, which shows a phase shift network incorporating the distributed varactor network of FIG. 3 to achieve up to a full 360° phase shift. Phase shift network system 500 has a phase shift network 502 composed of three distributed varactor networks 504a-c. Each one of the distributed varactor networks 504a-c is capable of achieving phase shift ranges of up to 120° and may be implemented, for example, as the distributed varactor network 300 of FIG. 3. In various examples, distributed varactor network 504a is capable of achieving phase shifts from 0 to 120°, distributed varactor network 504b is capable of achieving phase shifts from 120° to 240°, and distributed varactor network 504c is capable of achieving phase shifts from 240° to 360°.

The phase shift network 502 can be integrated with two 3-way RF switches, such as for example, SP3T switches 506 and 508. The switches 506-508 can be designed to have a loss of up to approximately 2.5 dB each. Since each distributed varactor network 504a-c has a loss of up to 6 dB at a frequency of 77 GHz, the phase shift network circuit 500 has a loss of up to 10-11 dB, which is significantly lower than the 18-20 dB loss typically experienced by conventional phase shift networks. The phase shift network circuit 500 is therefore capable of providing a full 360° phase shift range at a low loss in the millimeter wave spectrum, which as described above, is required to realize the full potential of many millimeter wave applications, including in autonomous driving where accurate object detection and classification are imperative.

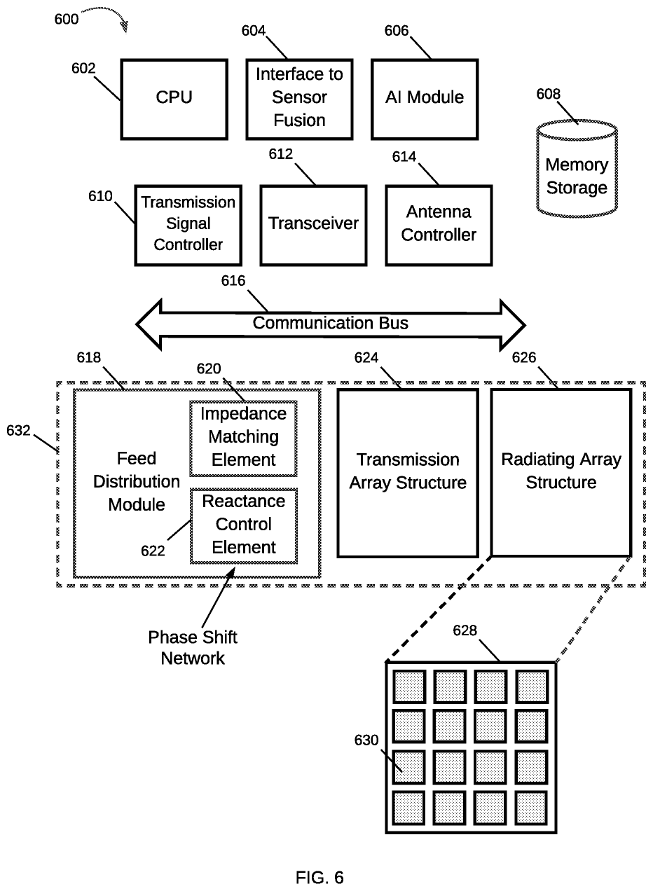

Referring now to FIG. 6, a schematic diagram of an example millimeter wave antenna system utilizing the phase shift network of FIG. 5 is described. Antenna system 600 includes modules such as radiating structure 632 coupled to an antenna controller 614, a central processor 602, and a transceiver 612. A signal is provided to antenna system 600 and the transmission signal controller 610 may act as an interface, translator or modulation controller, or otherwise as required for the signal to propagate through antenna system 600.

In various examples, the transmission signal controller 610 generates a transmission signal, such as a Frequency Modulated Continuous Wave (“FMCW”), which is used for example, in radar or other applications as the transmitted signal is modulated in frequency, or phase. The FMCW signal enables radar to measure range to an object by measuring the phase differences in phase or frequency between the transmitted signal and the received signal, or the reflected signal. Other modulation types may be incorporated according to the desired information and specifications of a system and application. Within FMCW formats, there are a variety of modulation patterns that may be used within FMCW, including triangular, sawtooth, rectangular and so forth, each having advantages and purposes. For example, sawtooth modulation may be used for large distances to a target; a triangular modulation enables use of the Doppler frequency, and so forth. The received information is stored in a memory storage unit 608, wherein the information structure may be determined by the type of transmission and modulation pattern.

In operation, the antenna controller 614 receives information from other modules in antenna system 600 indicating a next radiation beam, wherein a radiation beam may be specified by parameters such as beam width, transmit angle, transmit direction and so forth. The antenna controller 614 determines a voltage matrix to apply to capacitance control mechanisms coupled to the radiating structure 632 to achieve a given phase shift. The transceiver 612 prepares a signal for transmission, such as a signal for a radar device, wherein the signal is defined by modulation and frequency. The signal is received by each element of the radiating structure 632 and the phases of radiating patterns generated by the radiating array structure 626 is controlled by the antenna controller 614.

In various examples, transmission signals are received by a portion, or subarray, of the radiating array structure 626. These radiating array structures 626 are applicable to many applications, including radar in autonomous vehicles to detect objects in the environment of the car, or in wireless communications, medical equipment, sensing, monitoring, and so forth. Each application type incorporates designs and configurations of the elements, structures and modules described herein to accommodate their needs and goals.

Radiating structure 632 includes a feed distribution module 618 coupled to a transmission array structure 624 for transmitting signals through radiating array structure 626, which generates controlled radiation beams that may then be reflected back and ultimately analyzed by an AI module 606 and other sensor modules (not shown) in antenna system 600 for object detection and identification (e.g., in an autonomous driving application). An interface to sensor fusion module 604 interfaces with other sensor modules in antenna system 600 and a sensor fusion module (not shown) that processes the data from antenna system 600 and other sensors to detect and locate objects and provide an understanding of the surrounding environment. It is appreciated that antenna controller 614 may receive signals in response to processing of previous signals by AI module 606 or interface to sensor fusion module 604, or it may receive signals based on program information from memory storage unit 608.

The feed distribution module 618 has an impedance matching element 620 and a reactance control element 622. The impedance matching element 620 and the reactance control element 622 may be positioned within the architecture of feed distribution module 618. Alternatively, one or both of impedance matching element 620 and reactance control element 622 may be external to the feed distribution module 618 for manufacture or composition as an antenna or radar module. The impedance matching element 620 works in coordination with the reactance control element 622 to provide phase shifting of the radiating signal(s) from radiating array structure 626. In various examples, reactance control element 622 includes a reactance control mechanism controlled by antenna controller 614, which may be used to control the phase of a radiating signal from radiating array structure 16. Reactance control module may, for example, include a phase shift network system such as phase shift network system shown in FIG. 5 to provide any desired phase shift up to 360°.

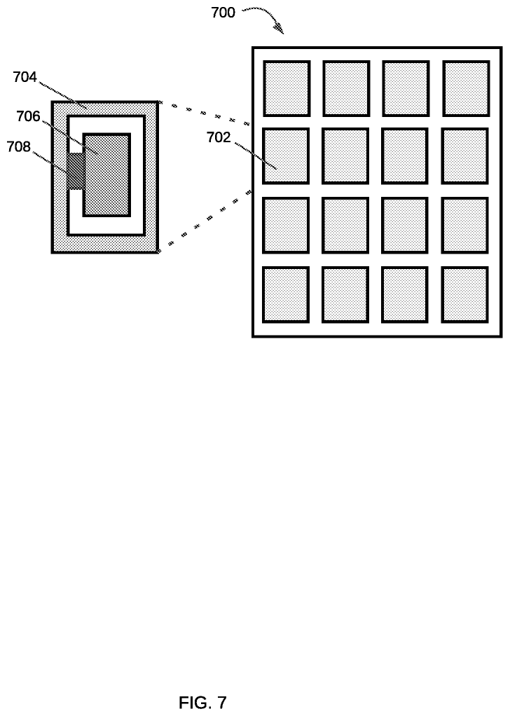

As illustrated, radiating structure 632 includes the radiating array structure 626, composed of individual radiating cells such as cell 630 and discussed in more detail herein below with reference to FIG. 7. The radiating array structure 626 may take a variety of forms and is designed to operate in coordination with the transmission array structure 624, wherein individual radiating cells (e.g., cell 630) correspond to elements within the transmission array structure 624. As illustrated, the radiating array structure 626 is an array of unit cell elements, wherein each of the unit cell elements has a uniform size and shape; however, some examples may incorporate different sizes, shapes, configurations and array sizes. When a transmission signal is provided to the radiating structure 632, such as through a coaxial cable or other connector, the signal propagates through the feed distribution module 618 to the transmission array structure 624 and then to radiating array structure 626 for transmission through the air.

Attention is now directed at FIG. 7, which shows a schematic diagram of an array of MTS cells such as array 628 of FIG. 6. Array 700 contains multiple MTS cells positioned in one or more layers of a substrate and coupled to other circuits, modules and layers, as desired and depending on the application. In some examples, the MTS cells are metamaterial cells in a variety of conductive structures and patterns, such that a received transmission signal is radiated therefrom. Each metamaterial cell may have unique properties. These properties may include a negative permittivity and permeability resulting in a negative refractive index; these structures are commonly referred to as left-handed materials (“LHM”). The use of LHM enables behavior not achieved in classical structures and materials, including interesting effects that may be observed in the propagation of electromagnetic waves, or transmission signals. Metamaterials can be used for several interesting devices in microwave and terahertz engineering such as antennas, sensors, matching networks, and reflector used in telecommunications, automotive and vehicular, robotic, biomedical, satellite and other applications. For antennas, metamaterials may be built at scales much smaller than the wavelengths of transmission signals radiated by the metamaterial. Metamaterial properties come from the engineered and designed structures rather than from the base material forming the structures. Precise shape, dimensions, geometry, size, orientation, arrangement and so forth result in the smart properties capable of manipulating electromagnetic waves by blocking, absorbing, enhancing, or bending waves. The MTS cells in array 700, such as MTS cell 702 may be arranged as shown or in any other configuration, such as, for example, in a hexagonal lattice.

MTS cell 702 is illustrated having a conductive outer portion or loop 704 surrounding a conductive area 706 with a space in between. Each MTS cell 702 may be configured on a dielectric layer, with the conductive areas and loops provided around and between different MTS cells. A voltage controlled variable reactance device 708, e.g., a varactor, provides a controlled reactance between the conductive area 706 and the conductive loop 704. The controlled reactance is controlled by an applied voltage, such as an applied reverse bias voltage in the case of a varactor. The change in capacitance changes the behavior of the MTS cell 702, enabling the MTS array 700 to provide focused, high gain beams directed to a specific location. It is appreciated that additional circuits, modules and layers may be integrated with the MTS array 700.

It is appreciated that antenna system 600 of FIG. 6 (with, for example, MTS array 700 as radiating array structure 628 and phase shift network system 500 incorporated in reactance control element 622) is applicable in wireless communication and radar applications, and in particular in MTS structures capable of manipulating electromagnetic waves using engineered radiating structures. It is also appreciated that antenna system 600 is capable of generating wireless signals, such as radar signals, having improved directivity, reduced undesired radiation patterns aspects, such as side lobes. Further, antenna system 600 is able to scan an entire environment in a fraction of the time of current systems. Antenna system 600 provides smart beam steering and beam forming using MTS radiating structures in a variety of configurations, wherein electrical changes to the antenna are used to achieve phase shifting and adjustment reducing the complexity and processing time and enabling fast scans of up to approximately 360° field of view for long range object detection.

It is further appreciated that antenna system 600 supports autonomous driving with improved sensor performance, all-weather/all-condition detection, advanced decision-making algorithms and interaction with other sensors through sensor fusion. These configurations optimize the use of radar sensors, as radar is not inhibited by weather conditions in many applications, such as for self-driving cars. The ability to capture environmental information early aids control of a vehicle, allowing anticipation of hazards and changing conditions. Antenna system 600 enables automotive radars capable of reconstructing the world around them and are effectively a radar “digital eye,” having true 3D vision and capable of human-like interpretation of the world, aided by the 360° phase shift provided by phase shift network system 500 of FIG. 5 integrated into antenna system 600.

It is appreciated that the previous description of the disclosed examples is provided to enable any person skilled in the art to make or use the present disclosure. Various modifications to these examples will be readily apparent to those skilled in the art, and the generic principles defined herein may be applied to other examples without departing from the spirit or scope of the disclosure. Thus, the present disclosure is not intended to be limited to the examples shown herein but is to be accorded the widest scope consistent with the principles and novel features disclosed herein.

What is claimed is:

1. A phase shift network system, comprising:
a phase shift network comprising a plurality of distributed varactor networks, each distributed varactor network capable of providing a phase shift range in a millimeter wave spectrum; and
a plurality of switches coupled to the phase shift network, each switch to activate a distributed varactor network from the plurality of distributed varactor networks to generate a given phase shift within the phase shift range.

2. The phase shift network system of claim 1, wherein the plurality of distributed varactor networks comprises three distributed varactor networks to provide a phase shift range of up to 360°, each of the three distributed varactor networks to achieve a phase shift of up to 120°.

3. The phase shift network system of claim 1, wherein each distributed varactor network from the plurality of distributed varactor networks comprises:
a first circuit section comprising a first and a second varactor coupled to a hybrid, 90° coupler; and
a second circuit section coupled to the first circuit section and comprising a third and a fourth varactor coupled to a hybrid, 45° coupler.

4. The phase shift network system of claim 3, wherein the first, second, third and fourth varactors comprise GaAs varactors operating in a millimeter wave spectrum.

5. The phase shift network system of claim 3, wherein the first, second, third and fourth varactors comprise GaAs varactors operating in a millimeter wave spectrum.

6. The phase shift network system of claim 3, wherein the first and the second varactor coupled to the hybrid, 90° coupler form an LC network.

7. The phase shift network system of claim 3, wherein the third and the fourth varactor coupled to the hybrid, 45° coupler form an LC network.

8. A distributed varactor network, comprising:
a first circuit section comprising a first and a second varactor coupled to a hybrid, 90° coupler; and
a second circuit section coupled to the first circuit section and comprising a third and a fourth varactor coupled to a hybrid, 45° coupler.

9. The distributed varactor network of claim 8, wherein the first, second, third and fourth varactors are GaAs varactors operating in a millimeter wave spectrum.

10. The distributed varactor network of claim 8, wherein the first circuit section coupled to the second circuit section achieve a phase shift of up to 120°.

11. A meta-structure antenna system, comprising:
an antenna controller for generating a transmission signal with controlled characteristics; and
a radiating structure to generate a radiating signal from the transmission signal, comprising:
a feed distribution module comprising a reactance control element, the reactance control element comprising a phase shift network system to generate a plurality of phase shifts within a phase shift range; and
a radiating array structure composed of an array of meta-structure cells coupled to the feed distribution module and the antenna controller, each meta-structure cell to generate a radiating signal at a given phase shift from the plurality of phase shifts.

12. The meta-structure antenna system of claim 11, wherein the phase shift network system comprises a plurality of distributed varactor networks and a plurality of switches, each switch to activate a distributed varactor network to generate the given phase shift within the phase range.

13. The meta-structure antenna system of claim 12, wherein each distributed varactor network comprises:
a first circuit section comprising a first and a second varactor coupled to a hybrid, 90° coupler; and
a second circuit section coupled to the first circuit section and comprising a third and a fourth varactor coupled to a hybrid, 45° coupler.

14. The meta-structure antenna system of claim 13, wherein the first, second, third and fourth varactors comprise GaAs varactors operating in a millimeter wave spectrum.

15. The meta-structure antenna system of claim 13, wherein the first, second, third and fourth varactors comprise Si varactors operating in a millimeter wave spectrum.

16. The meta-structure antenna system of claim 13, wherein the first circuit section forms a first LC network and the second circuit section forms a second LC network.

17. The meta-structure antenna system of claim 13, wherein the plurality of distributed varactor networks comprises three distributed varactor networks, each of the three distributed varactor networks to generate phase shifts within a 120° phase range.

18. The meta-structure antenna system of claim 12, wherein the meta-structure cells comprise metamaterial cells.

19. The meta-structure antenna system of claim 12, further comprising an AI module for object detection and identification in echoes generated from the radiating signal.

20. The meta-structure antenna system of claim 18, further comprising an interface to sensor fusion module coupled to the AI module.
